(19) United States
(12) Patent Application Publication
(10) Pub. No.: US 2002/0155724 A1
(43) Pub. Date: Oct. 24, 2002

(54) Dry etching method and apparatus

(75) Inventors: Takayuki Sakai, Chofu-shi (JP); Tokuhisa Ohiwa, Kawasaki-shi (JP)

Correspondence Address: Finnegan, Henderson, Farabow,, Garrett & Dunner, L.L.P., 1300 I Street, N.W., Washington, DC, 20005-3315, US

(73) Assignee: KABUSHIKI KAISHA TOSHIBA

(21) Appl. No.: 10/124,247

(22) Filed: Apr. 18, 2002

(30) Foreign Application Priority Data
Apr. 19, 2001 (JP) 2001-121257

(51) Int. Cl. H01L 21/302; H01L 21/461

(52) U.S. Cl. 438/710

(57) ABSTRACT

In dry etching a semiconductor workpiece, a mixture of a carbon-free, fluorine-containing gas and a fluorine-free, carbon-containing gas is used as an etching gas.

### CROSS-REFERENCE TO RELATED APPLICATIONS

This application is based upon and claims the benefit of priority from the prior Japanese Patent Application No. 2001-121257, filed Apr. 19, 2001, the entire contents of which are incorporated herein by reference.

### BACKGROUND OF THE INVENTION

1. Field of the Invention

The present invention relates to a dry etching method and apparatus for use in manufacturing semiconductor devices, and more particularly to a dry etching method and apparatus, which do not use fluorocarbons as an etching gas.

2. Description of the Related Art

In manufacturing semiconductor devices, dry etching is performed to selectively etch a substrate or an insulating film formed on the substrate. Fluorocarbon gases are often used as an etching gas to etch an insulating film formed on the substrate. The fluorocarbon gases can etch, for example, a silicon oxide film formed on a silicon substrate at a sufficient rate. On the other hand, the fluorocarbon gases form a fluorocarbon film on the surface of the silicon substrate. Accordingly, the fluorocarbon gases exhibit a very low etching rate for silicon. Thus, the fluorocarbon gases can etch the silicon oxide film with a high selectivity to silicon.

However, fluorocarbons are ozone-depleting substances. In addition, they are greenhouse gases like carbon dioxide, and are a major factor of global warming. In particular, fluorocarbon gases have a high GWP (global warming potential). In order to inhibit the global warming, the semiconductor industries are required to drastically reduce the amount of fluorocarbon gases used, in particular, PFCs (perfluorocompounds). Under the circumstances, there is a strong demand for alternative gases for fluorocarbon gases used as etching gases in the dry etching process.

### BRIEF SUMMARY OF THE INVENTION

According to a first aspect of the present invention, there is provided a dry etching method comprising:

introducing an etching gas comprising a carbon-free, fluorine-containing gas and a fluorine-free, carbon-containing gas into a process chamber that accommodates a semiconductor workpiece; and

generating a plasma from the etching gas and subjecting the semiconductor workpiece to etching by the plasma.

According to a second aspect of the present invention, there is provided a method of etching a semiconductor workpiece, comprising:

(a) accommodating, in a process chamber, a semiconductor workpiece comprising a silicon substrate and a silicon oxide film formed on the silicon substrate;

(b) introducing a first etching gas comprising a carbon-free, fluorine-containing gas and a fluorine-free, carbon-containing gas into the process chamber, with a ratio between the fluorine-containing gas and the carbon-containing gas in the first etching gas controlled such that the oxide film is etched preferentially to the substrate;

(c) generating a first plasma from the first etching gas and subjecting the oxide film to etching by the first plasma, to form an opening in the oxide film, which partially exposes of a surface of the substrate;

(d) subsequent to the formation of the opening in the oxide film, introducing a second etching gas comprising a carbon-free, fluorine-containing gas and a fluorine-free, carbon-containing gas into the process chamber, with a ratio between the fluorine-containing gas and the carbon-containing gas in the second etching gas controlled such that the substrate is etched preferentially to the oxide film; and

(e) generating a second plasma from the second etching gas and subjecting the substrate to etching by the second plasma through the opening in the oxide film.

According to a third aspect of the present invention, there is provided a dry etching apparatus comprising:

a process chamber in which a semiconductor workpiece is to be placed;

a first device configured to introduce an etching gas comprising a carbon-free, fluorine-containing gas and a fluorine-free, carbon-containing gas into the process chamber; and

a second device configured to generate a plasma from the etching gas.

### BRIEF DESCRIPTION OF THE SEVERAL VIEWS OF THE DRAWING

FIG. 1 schematically shows a fundamental construction of a dry etching apparatus according to an embodiment of the present invention;

FIGS. 2A and 2B are cross-sectional views illustrating a process of dry-etching a silicon oxide film formed on a silicon substrate according to an embodiment of the invention;

FIG. 3 is a cross-sectional view illustrating a process of dry-etching a silicon substrate with a silicon oxide film used as a mask according to an embodiment of the invention;

FIG. 4 is a graph showing a relationship between etching rates of silicon and silicon oxide, on one hand, and a proportion of an ethanol gas in a dry etching gas, on the other hand;

FIG. 5 is a graph showing a surface analysis result of a silicon substrate after a silicon oxide film formed on the silicon substrate has been subjected to dry etching according to an embodiment of the invention;

FIG. 6 is a graph showing a relationship between etching rates of silicon and silicon oxide, on one hand, and a proportion of a methane gas in a dry etching gas, on the other hand; and

FIG. 7 is a graph showing a relationship between etching rates of silicon and silicon oxide, on one hand, and a proportion of a methane gas in a dry etching gas, on the other hand.

### DETAILED DESCRIPTION OF THE INVENTION

Embodiments of the present invention will now be described.

According to an embodiment of the invention, a mixture of a carbon-free, fluorine-containing gas and a fluorine-free, carbon-containing gas is used as an etching gas in dry etching of a semiconductor workpiece, e.g., a semiconductor wafer.

According to an embodiment of the invention, first, a semiconductor wafer to be subjected to dry etching is placed in a process chamber. The semiconductor wafer may usually include a semiconductor substrate, such as a silicon substrate, and an oxide film, such as a silicon oxide film, provided on the semiconductor substrate.

The process chamber may be a commonly used chamber for dry etching. A plasma generating mechanism is provided within the process chamber. Further, the process chamber is provided with at least one gas inlet conduit for introducing a dry etching gas, and a gas outlet conduit for exhausting a gas from the process chamber. The gas outlet conduit is connected to an exhaust system for evacuating the process chamber.

The plasma generating mechanism provided within the process chamber may comprise a pair of parallel plate electrodes (cathode and anode) oppositely disposed, spaced apart from each other. A predetermined high-frequency power supplied from a high-frequency power source is applied across the electrodes to generate a plasma from the etching gas. The semiconductor wafer is placed on the lower electrode (usually, the cathode).

After the semiconductor wafer is placed in the process chamber, the process chamber is sufficiently evacuated. Following the evacuation, a carbon-free, fluorine-containing gas and a fluorine-free, carbon-containing gas are introduced into the process chamber.

The carbon-free, fluorine-containing gas is a gas of a substance that contains no carbon, and hence is an inorganic, fluorine-containing substance. Examples of the inorganic fluorine-containing substance may include fluorine (F₂), nitrogen trifluoride (NF₃), hydrogen fluoride (HF), chlorine trifluoride (ClF₃), sulfur hexafluoride (SF₆), boron trifluoride (BF₃), and bromine trifluoride (BrF₃). These carbon-free, fluorine-containing gases may be used singly or in combination.

The fluorine-free, carbon-containing gas is a gas of a substance that contains no fluorine, but contains carbon. Such a carbon-containing substance may generally be represented by a molecular formula: CₓH_{y}O_{z} where x is an integer of 1 or more, y is an integer of 0 or more, and z is an integer of 0 or more. More specifically, the carbon-containing gas includes an organic compound and/or carbon monoxide (CO). The organic compound may usually be gas, liquid or subliming solid at room temperature (about 20° C.). The organic compound includes hydrocarbons such as aliphatic hydrocarbons, e.g., C₁-C₇ hydrocarbons such as methane and ethane, and aromatic hydrocarbons, e.g., naphthalene; alcohols such as alkanols, e.g., C₁-C₇ alkanols such as methanol and ethanol, and aromatic alcohols; aldehydes, e.g., C₁-C₇ aldehydes; ketones, e.g., C₂ -C₇ ketones; and ethers, e.g., C₂ -C₇ ethers. These fluorine-free, carbon-containing gases may be used singly or in combination.

The carbon-free, fluorine-containing gas (hereinafter referred to simply as “fluorine-containing gas”) and the fluorine-free, carbon-containing gas (hereinafter referred to simply as “carbon-containing gas”) may be introduced into the process chamber at a total flow rate of, usually, about 50 sccm to about 500 sccm, and more usually about 100 sccm to about 200 sccm. In addition, these gases may be introduced into the process chamber along with a carrier/diluent gas (e.g., an inert gas such as argon). The carrier gas, if used, may be introduced into the process chamber at a flow rate of about 100 to about 500 sccm. In dry etching, the internal pressure of the process chamber may be set usually at about 0.1 Pa to about 100 Pa, and more usually, at 1 Pa to 20 Pa. The atmosphere within the process chamber during dry etching may be set at temperatures from room temperature (about 20° C.) to about 80° C. Subsequently, a high-frequency power is applied across the parallel plate electrodes to produce a plasma from a mixture of the fluorine-containing gas and the carbon-containing gas. Usually, the high-frequency power can be applied at a power density of 3 to 8 W/cm². In this way, the semiconductor wafer is subjected to etching by the generated plasma.

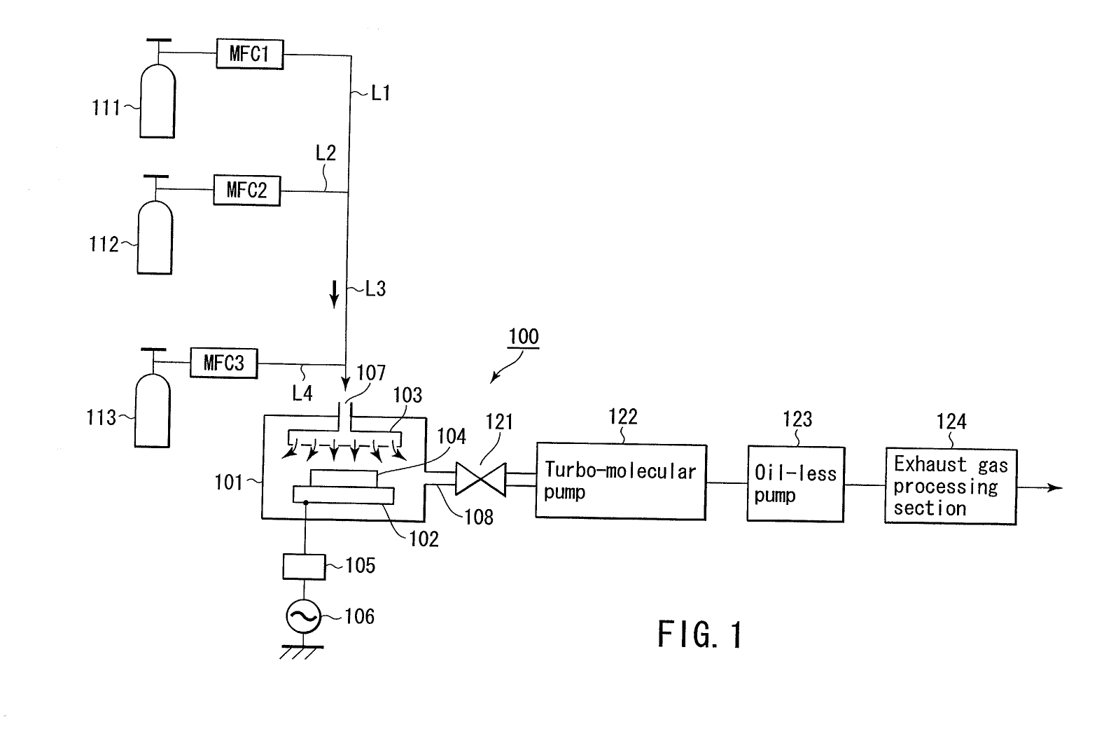

FIG. 1 schematically shows a fundamental construction of a dry etching apparatus, which may be used in carrying out a dry etching method according to an embodiment of the present invention.

A dry etching apparatus 100 shown in FIG. 1 has a process chamber 101. Within the process chamber 101, a parallel plate-type plasma generating mechanism is provided which comprises a cathode 102 and an anode 103 arranged in parallel to face each other. A semiconductor wafer 104 to be subjected to dry etching is placed on the cathode 102. A high-frequency power source 106 of, e.g., 13.56 MHz, is connected to the cathode 102 via a matching circuit 105. The process chamber 101 is provided with an inlet port 107 for introducing a plasma generating gas (etching gas) and an outlet port 108 for exhausting gases from the chamber 101.

A fluorine-containing gas is supplied from a cylinder 111 that is a supply source thereof. A carbon-containing gas is supplied from a cylinder 112 that is a supply source thereof.

The fluorine-containing gas from the cylinder 111 flows in a line L1 provided with a mass flow controller MFC1 that controls the flow rate of this gas. On the other hand, the carbon-containing gas from the cylinder 112 flows in a line L2 provided with a mass flow controller MFC2 that controls the flow rate of this gas. The lines L1 and L2 merge into a single line L3. The mixture gas of the fluorine-containing gas and the carbon-containing gas, which flows in the line L3, is introduced into the process chamber 101 from the gas inlet port 107. The ratio between the fluorine-containing gas and carbon-containing gas can be controlled by the mass flow controllers MFC1 and MFC2.

If a carrier gas is used, a cylinder 113 filled with the carrier gas is further provided. The carrier gas from the cylinder 113 flows in a line L4 provided with a mass flow controller MFC3 that controls the flow rate of this gas. The line L4 joins the line L3. Thus, the carrier gas, if used, is introduced into the process chamber 101 along with the mixture of the fluorine-containing gas and the carbon-containing gas.

Where the etching gas source substance is in a liquid state at room temperature, like, e.g., methanol or ethanol, a mass flow controller operable with a slight pressure difference may be used for the mass flow controller MFC2. Such a mass flow controller allows the liquid substance in the cylinder to flow as a gas at a certain flow rate (e.g., several-ten sccm) when evacuation is effected by a turbo-molecular pump and an oil-less pump (to be described later). However, the cylinder and/or the line may be sufficiently heated in order to obtain a gas from the liquid substance at a higher flow rate.

A turbo-molecular pump 122 is connected to the gas outlet port 108 of the process chamber 101 via a pressure-adjusting valve 121. An oil-less pump 123 is connected to the exhaust side of the turbo-molecular pump 122. The process chamber 101 can be evacuated by the turbo-molecular pump 122 and oil-less pump 123. The exhaust side of the oil-less pump 123 is connected to an exhaust gas processing section 124. The exhaust gas processing section 124 removes, or renders harmless, components of the gas, which may be harmful, coming from the process chamber 101. The outlet side of the exhaust gas processing section 124 is connected to an exhaust duct (not shown), and the processed gas is released outside the system via the exhaust duct. Note that conventional valves, heaters and other accessories are not shown in FIG. 1 for simplicity.

In the process chamber 101, the semiconductor wafer 104 is subjected to dry etching under the above-described conditions. Accordingly, an oxide film or a semiconductor material in the semiconductor wafer 104 can be etched.

It should be noted that a dry etching according to an embodiment of the invention can be conducted by using not only a parallel plate type etching apparatus such as that described above with reference to FIG. 1, but also other etching apparatuses having other plasma generating mechanisms such as inductively coupled type and electron cyclotron resonance (ECR) type etching apparatuses.

In the dry etching, a mixture of the fluorine-containing gas and the carbon-containing gas exhibits unique behaviors. The behaviors will be explained in detail below by taking, as an example, a case where a silicon substrate and a silicon oxide film are etched.

When the proportion of the carbon-containing gas to the total amount of the fluorine-containing gas and the carbon-containing gas is lower, the Si/SiO₂ selective etching ratio (the ratio of the etching rate of silicon to the etching rate of silicon oxide film) becomes higher. When a fluorine-containing gas such as fluorine gas is used singly, it can etch the silicon at approximately double the etching rate of the silicon oxide film. As the proportion of the carbon-containing gas is increased, both the etching rate of silicon and the etching rate of silicon oxide film decrease. In this case, however, the rate of decrease in the etching rate of silicon is significantly greater than the rate of decrease in the etching rate of silicon oxide film. Later on, the etching rate of silicon becomes equal to that of silicon oxide film (the volume proportion of the carbon-containing gas at the moment when the etching rate of silicon has become equal to that of silicon oxide film, i.e., the volume percentage of the carbon-containing gas in the total volume of the fluorine-containing gas and the carbon-containing gas, is herein referred to as “equi-velocity point volume percentage”). As the proportion of the carbon-containing gas is increased beyond the equi-velocity point volume percentage, the etching rate of the silicon oxide film becomes higher than that of the silicon, and at last the etching rate of the silicon becomes zero (the volume proportion of the carbon-containing gas at the moment when the etching rate of silicon has become zero is herein referred to as “zero-velocity point volume percentage”). When the proportion of the carbon-containing gas is increased to a level not lower than the zero-velocity point volume percentage, only the silicon oxide film will be etched.

These behaviors of a mixture of the fluorine-containing gas and the carbon-containing gas can be confirmed by preliminary experiments. For example, when a fluorine gas and an ethanol gas are used, the equi-velocity point volume percentage and the zero-velocity point volume percentage of the ethanol gas may vary depending on etching conditions, but may be about 6% and about 15%, respectively. When a nitrogen trifluoride gas and a methane gas are used, the equi-velocity point volume percentage and the zero-velocity point volume percentage of the methane gas may vary depending on etching conditions, but may be about 8-9% and about 20%, respectively. When a fluorine gas and a methane gas are used, the equi-velocity point volume percentage and the zero-velocity point volume percentage of the methane gas may vary depending on etching conditions, but may be about 10% and about 23%, respectively.

Accordingly, by controlling the proportion of the carbon-containing gas to the total amount of the fluorine-containing gas and the carbon-containing gas, an oxide (e.g., silicon oxide) of a semiconductor material (e.g., silicon) can be etched selectively with respect to the semiconductor material, or the semiconductor material can be etched selectively with respect to the oxide. Specifically, if the proportion of the carbon-containing gas to the total amount of the fluorine-containing gas and the carbon-containing gas is set at a level higher than 0%, but lower than the equi-velocity point volume percentage, the semiconductor material may be etched preferentially to the oxide film. On the other hand, if the proportion of the carbon-containing gas to the total amount of the fluorine-containing gas and the carbon-containing gas is set at a level higher than the equi-velocity point volume percentage, the oxide film may be etched preferentially to the semiconductor material. Obviously, the etching of the oxide film and the etching of the semiconductor material can be successively performed by using the same fluorine-containing gas and carbon-containing gas and varying the ratio therebetween. In order to etch the silicon selectively with respect to the silicon oxide, the proportion of the carbon-containing gas to the total amount of the fluorine-containing gas and carbon-containing gas may be set at a level at which Si/SiO₂ selective etching ratio becomes more than 1. On the other hand, in order to selectively etch the silicon oxide with respect to the silicon, the proportion of the carbon-containing gas to the total amount of the fluorine-containing gas and carbon-containing gas may be set at a level at which SiO₂/Si selective etching ratio becomes about 2 or more.

It has been found that a mixture of the fluorine-containing gas and the carbon-containing gas produces a fluorocarbon film on a silicon surface during the etching. More specifically, under the conditions that the oxide film is etched preferentially to the silicon, fluorocarbon is formed on a silicon surface, which is exposed when an oxide film has been etched. This fluorocarbon prevents etching of the silicon. On the other hand, under the conditions that the silicon is etched preferentially to the silicon oxide, the silicon is etched in a direction vertical to the substrate surface. A fluorocarbon film is formed on inner sidewalls of an opening such as a hole or a groove created in the silicon by the etching. This fluorocarbon film prevents lateral etching of the silicon. In a case where a fluorine-containing gas, e.g., fluorine gas, is used singly, the silicon is also laterally etched. The fluorocarbon film formed on the silicon substrate can be removed by conventional O₂-ashing.

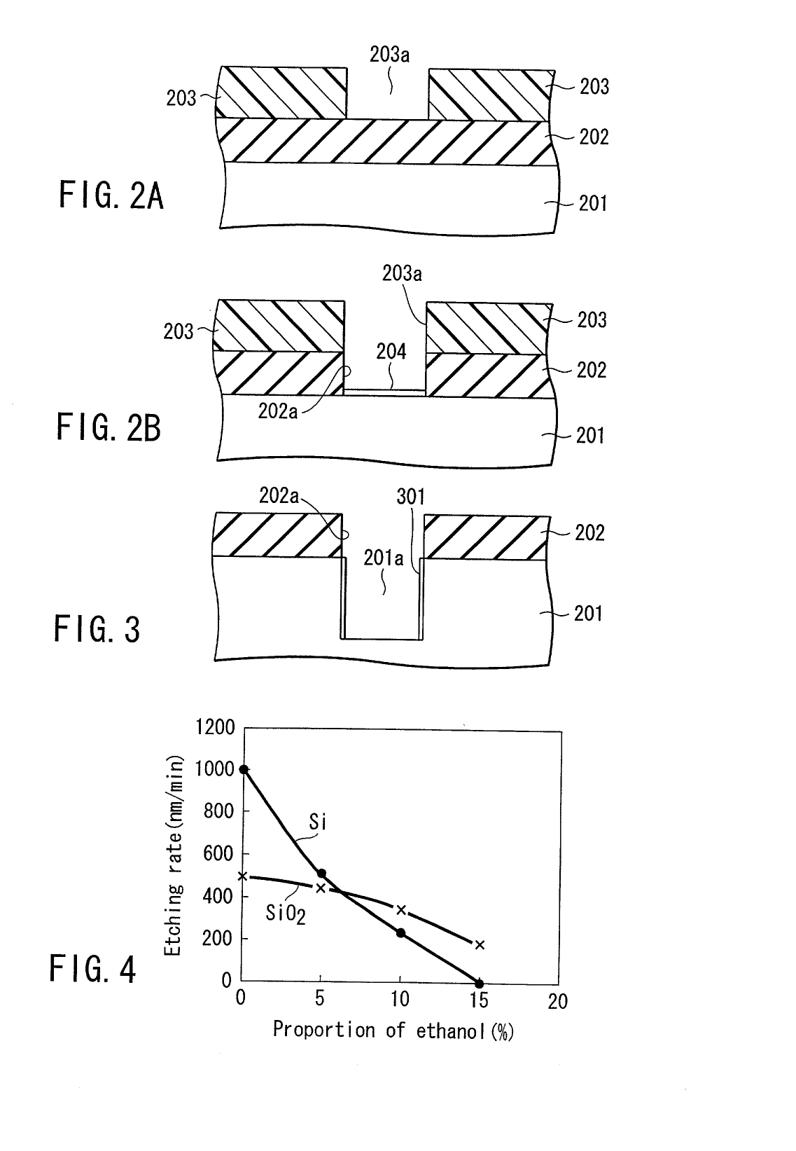

FIGS. 2A and 2B are cross-sectional views illustrating a process of selectively etching an oxide film on a semiconductor substrate according to an embodiment of the invention.

As shown in FIG. 2A, an oxide film, in particular a silicon oxide film 202, is formed on a semiconductor substrate, in particular a silicon substrate 201. A photoresist is coated over the oxide film 202, and the photoresist coating film is processed by a well-known photo-process. Thus, a resist mask 203, in which an opening (hole or groove) 203a is defined, is formed.

As shown in FIG. 2B, the oxide film 202 is selectively etched using a fluorine-containing gas and a carbon-containing gas, under the dry etching conditions as described above in detail. The proportion of the carbon-containing gas to the total amount of the fluorine-containing gas and the carbon-containing gas is set at a level higher than the equi-velocity point volume percentage, preferably at a level not lower than the zero-velocity point volume percentage. At this time, a fluorocarbon film 204 deposits on a surface of the silicon substrate 201, which has been exposed by the etching of the oxide film 202. The fluorocarbon film 204 prevents the surface of the silicon substrate 201 from being etched. Thus, an opening (hole or groove) 202a corresponding to the opening 203a in the resist mask 203 is formed in the oxide film 202.

FIG. 3 is a cross-sectional view illustrating a process of etching a silicon substrate with a silicon oxide film used as a mask.

First, an oxide mask 202, which defines an opening (hole or groove) 202a therein, is formed on a semiconductor substrate 201. The oxide mask 202 may be advantageously formed by the procedures described with reference to FIGS. 2A and 2B.

Subsequently, the substrate 201 is selectively etched using a fluorine-containing gas and a carbon-containing gas, under the dry etching conditions as described above in detail. The proportion of the carbon-containing gas to the total amount of the fluorine-containing gas and the carbon-containing gas is set at a level higher than zero, but lower than the equi-velocity point volume percentage. At this time, a fluorocarbon film 301 deposits on the etched side faces in the semiconductor. The fluorocarbon film 301 prevents lateral etching of the semiconductor. Thus, the semiconductor material can be etched in a vertical direction. In this way, an opening (hole or groove) 201a corresponding to the opening 202a in the oxide mask 202 is formed in the semiconductor substrate 201.

Examples of the present invention will now be described below.

### EXAMPLE 1

In this Example, a dry etching apparatus having the same structure as the apparatus shown in FIG. 1 was used. Fluorine gas (F₂) was used as a fluorine-containing gas, and ethanol (C₂H₅OH) was used as a carbon-containing gas.

A silicon wafer and a silicon oxide wafer were placed in the process chamber. The pressure within the process chamber was kept at 5 Pa, and a high-frequency power was applied across the parallel plate electrodes at a power density of 5 W/cm². The total flow rate of the fluorine gas and the ethanol gas was kept constant at 100 sccm, with the ratio of the fluorine gas and the ethanol gas varied. Under these conditions, the etching rate of silicon and that of silicon oxide (SiO₂) were measured. FIG. 4 shows the relationship between the etching rates of the silicon and silicon oxide, on one hand, and the volume percentage (proportion) of the ethanol gas in the total volume of the fluorine gas and the ethanol gas, on the other hand.

As seen from FIG. 4, when the proportion of the fluorine gas is 100%, the etching rate of silicon is 1000 nm/min, which is nearly equal to double the etching rate of silicon oxide. At the moment when the proportion of the ethanol gas is increased to reach about 6% by volume (i.e., the equi-velocity point volume percentage), the etching rate of silicon and that of silicon oxide become substantially equal. At the moment when the proportion of the ethanol gas is increased to reach about 15% by volume (i.e., the zero-velocity point volume percentage), the etching rate of silicon becomes nearly zero. Since the etching rate of silicon oxide is about 200 nm/min at this time, the selective etching ratio of silicon oxide to silicon becomes infinite.

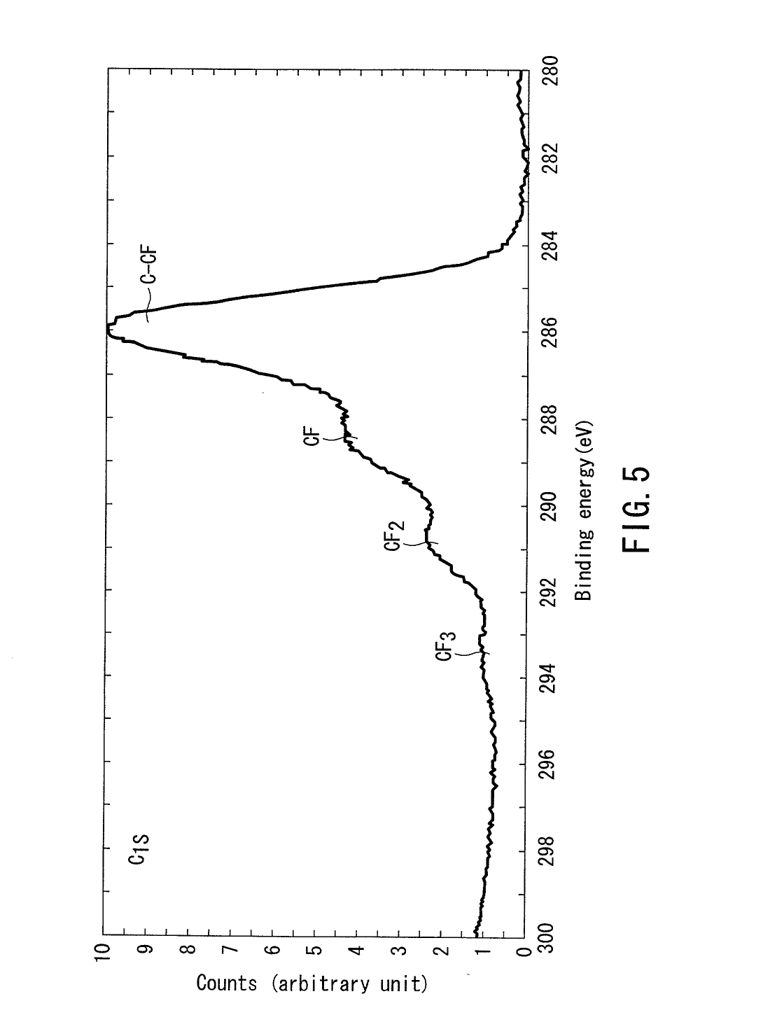

The surface of the silicon substrate at this time was analyzed by XPS (X-ray photoelectron spectroscopy). FIG. 5 shows a spectrum of C₁ₛ (1s core level of carbon) obtained by this analysis. In FIG. 5, sub-peaks of carbon due to CFₓ bonds appear, which reveals that a fluorocarbon film deposits on the surface. In a conventional etching of an insulating film with a fluorocarbon gas, it is known that an etching protection film of fluorocarbon deposits on the surface of the silicon substrate. It has been found, however, that even when a fluorine gas and an ethanol gas are used, instead of fluorocarbon gases, an etching protection film formed of a fluorocarbon can be formed on the surface. Thus, it has been confirmed that the silicon oxide (SiO₂) can be etched selectively with respect to the silicon.

### EXAMPLE 2

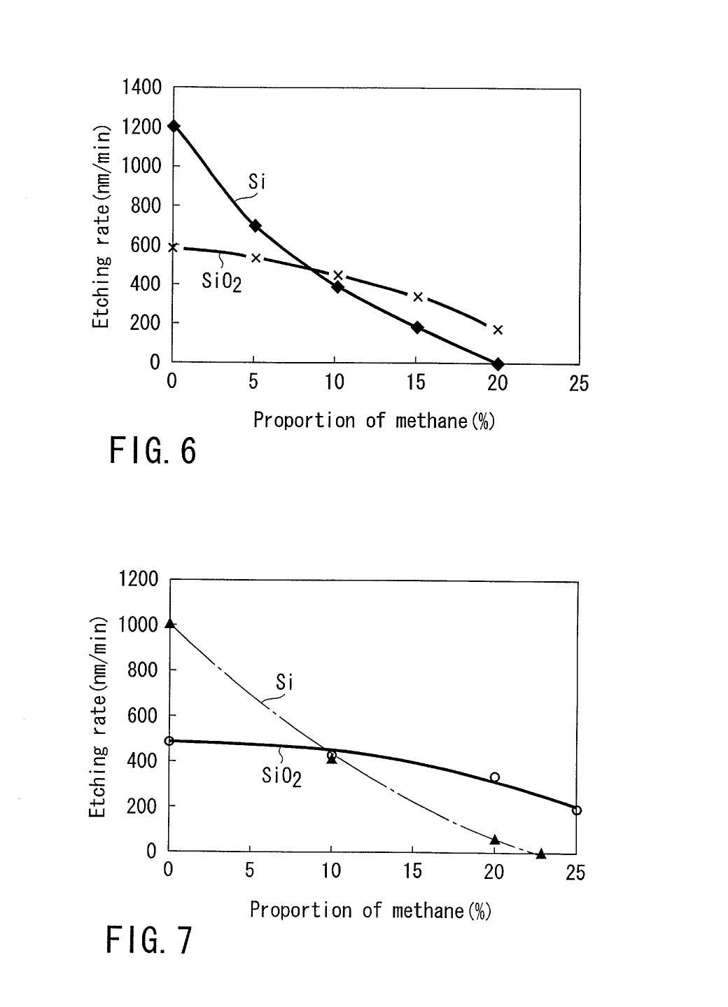

A silicon wafer and a silicon oxide wafer were etched by the same procedures as in Example 1, except that a nitrogen trifluoride gas was used as a fluorine-containing gas, and a methane gas was used as a carbon-containing gas, with the ratio of theses gases varied. FIG. 6 shows the relationship between the etching rates of silicon and silicon oxide, on one hand, and the proportion of the methane gas to the total volume of the nitrogen trifluoride gas and the methane gas, on the other hand.

As seem from FIG. 6, when the proportion of the nitrogen trifluoride gas is 100%, the etching rate of silicon is 1200 nm/min, which is nearly equal to double the etching rate of silicon oxide. At the moment when the proportion of the methane gas is increased to reach about 8-9% by volume (i.e., the equi-velocity point volume percentage), the etching rate of silicon and that of silicon oxide become substantially equal. At the moment when the proportion of the methane gas is increased to reach about 20% by volume (i.e., the zero-velocity point volume percentage), the etching rate of silicon becomes nearly zero. Since the etching rate of silicon oxide is about 200 nm/min at this time, the selective etching ratio of silicon oxide to silicon becomes infinite.

The surface of the silicon substrate at this time was analyzed by XPS, which revealed that a fluorocarbon film deposits on the surface of the silicon substrate, as in Example 1.

### EXAMPLE 3

A silicon wafer and a silicon oxide wafer were etched by the same procedures as in Example 1, except that a fluorine gas was used as a fluorine-containing gas, and a methane gas was used as a carbon-containing gas, with the ratio of theses gases varied. FIG. 7 shows the relationship between the etching rates of silicon and silicon oxide, on one hand, and the proportion of the methane gas to the total volume of the fluorine gas and the methane gas, on the other hand.

As seem from FIG. 7, when the proportion of the fluorine gas is 100%, the etching rate of silicon is 1000 nm/min, which is nearly equal to double the etching rate of silicon oxide. At the moment when the proportion of the methane gas is increased to reach about 10% by volume (i.e., the equi-velocity point volume percentage), the etching rate of silicon and that of silicon oxide become substantially equal. At the moment when the proportion of the methane gas is increased to reach about 23% by volume (i.e., the zero-velocity point volume percentage), the etching rate of silicon becomes nearly zero. Since the etching rate of silicon oxide is about 300 nm/min at this time, the selective etching ratio of silicon oxide to silicon becomes infinite.

The surface of the silicon substrate at this time was analyzed by XPS, which revealed that a fluorocarbon film deposits on the surface of the silicon substrate, as in Example 1.

### EXAMPLE 4

(A) Etching of Silicon Oxide Film

As has been described with reference to FIG. 2A, a resist mask 203 was formed on a silicon oxide film 202 provided on a silicon substrate 201.

Subsequently, the silicon oxide film 202 was etched, using the dry etching apparatus shown in FIG. 1. A mixture of fluorine and ethanol gases, containing 15% by volume of ethanol gas, was used as an etching gas. The pressure within the process chamber was kept at 5 Pa. The total flow rate of the fluorine gas and the ethanol gas was kept at 100 sccm. The power density of the high-frequency power applied across the cathode and anode was 5 W/cm². Thus, the silicon oxide film 202 was etched, as shown in FIG. 2B. It was confirmed by the XPS analysis that a fluorocarbon film 204 was formed on a surface portion of silicon substrate 201 that had been exposed by the etching of the oxide film 202.

(B) Etching of Silicon Substrate

Subsequent to the procedures (A) above, the resist mask 203 was removed by O₂-ashing, and the process chamber was then evacuated. Thereafter, the silicon substrate 201 was etched under the same etching conditions as in the procedures (A) above, except that the proportion of the ethanol gas in the mixture of the fluorine gas and ethanol gas was set at 1-2% by volume, with the oxide film 202, which had been etched in the procedures (A) above, used as a mask, as shown in FIG. 3. It was confirmed by the XPS analysis that a fluorocarbon film 301 was formed on sidewalls of a groove 201a created in the silicon.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A dry etching method comprising:
introducing an etching gas comprising a carbon-free, fluorine-containing gas and a fluorine-free, carbon-containing gas into a process chamber that accommodates a semiconductor workpiece; and
generating a plasma from said etching gas and subjecting said semiconductor workpiece to etching by said plasma.

2. The method according to claim 1, wherein said fluorine-containing gas is selected from the group consisting of fluorine, nitrogen trifluoride, hydrogen fluoride, chlorine trifluoride, sulfur hexafluoride, boron trifluoride, bromine trifluoride, and a mixture thereof.

3. The method according to claim 1, wherein said carbon-containing gas is represented by a molecular formula: CₓH_{y}O_{z} where x is an integer of 1 or more, y is an integer of 0 or more, and z is an integer of 0 or more.

4. The method according to claim 1, wherein said fluorine-containing gas and said carbon-containing gas are introduced into the process chamber at a total flow rate of from about 50 sccm to about 500 sccm.

5. The method according to claim 1, wherein a pressure within the process chamber is kept at a level of from about 0.1 Pa to about 100 Pa.

6. The method according to claim 1, wherein said semiconductor workpiece comprises a semiconductor and an oxide film provided on the semiconductor.

7. The method according to claim 6, wherein a ratio between said fluorine-containing gas and said carbon-containing gas introduced into the process chamber is controlled such that said oxide film is etched preferentially to said semiconductor.

8. The method according to claim 7, wherein a proportion of said carbon-containing gas in a total volume of said fluorine-containing gas and said carbon-containing gas is set at a level higher than an equi-velocity point volume percentage, as herein defined, of said carbon-containing gas.

9. The method according to claim 7, wherein a proportion of said carbon-containing gas in a total volume of said fluorine-containing gas and said carbon-containing gas is set at a level equal to or higher than a zero-velocity point volume percentage, as herein defined, of said carbon-containing gas.

10. The method according to claim 6, wherein a ratio between said fluorine-containing gas and said carbon-containing gas introduced into the process chamber is controlled such that said semiconductor is etched preferentially to said oxide film.

11. The method according to claim 10, wherein a proportion of said carbon-containing gas in a total volume of said fluorine-containing gas and said carbon-containing gas is set at a level higher than 0%, but lower than an equi-velocity point volume percentage, as herein defined, of said carbon-containing gas.

12. A method of etching a semiconductor workpiece, comprising:
(a) accommodating, in a process chamber, a semiconductor workpiece comprising a silicon substrate and a silicon oxide film formed on said silicon substrate;
(b) introducing a first etching gas comprising a carbon-free, fluorine-containing gas and a flourine-free, carbon-containing gas into said process chamber, with a ratio between said fluorine-containing gas and said carbon-containing gas in said first etching gas controlled such that said oxide film is etched preferentially to said substrate;
(c) generating a first plasma from said first etching gas and subjecting said oxide film to etching by said first plasma, to form an opening in said oxide film, which partially exposes of a surface of said substrate;
(d) subsequent to the formation of said opening in said oxide film, introducing a second etching gas comprising a carbon-free, fluorine-containing gas and a fluorine-free, carbon-containing gas into said process chamber, with a ratio between said fluorine-containing gas and said carbon-containing gas in said second etching gas controlled such that said substrate is etched preferentially to said oxide film; and
(e) generating a second plasma from said second etching gas and subjecting said substrate to etching by said second plasma through said opening in said oxide film.

13. The method according to claim 12, wherein said fluorine-containing gas is selected from the group consisting of fluorine, nitrogen trifluoride, hydrogen fluoride, chlorine trifluoride, sulfur hexafluoride, boron trifluoride, bromine trifluoride, and a mixture thereof.

14. The method according to claim 12, wherein said carbon-containing gas is represented by a molecular formula: CₓH_{y}O_{z} where x is an integer of 1 or more, y is an integer of 0 or more, and z is an integer of 0 or more.

15. The method according to claim 12, wherein in each of said (b) and (d), said fluorine-containing gas and said carbon-containing gas are introduced into said process chamber at a total flow rate of from about 50 sccm to about 500 sccm.

16. The method according to claim 12, wherein in each of said (c) and (e), a pressure within said process chamber is kept at a level of from about 0.1 Pa to about 100 Pa.

17. The method according to claim 12, wherein a proportion of said carbon-containing gas in a total volume of said fluorine-containing gas and said carbon-containing gas in said first etching gas is set at a level higher than an equi-velocity point volume percentage, as herein defined, of said carbon-containing gas.

18. The method according to claim 12, wherein a proportion of said carbon-containing gas in a total volume of said fluorine-containing gas and said carbon-containing gas in said second etching gas is set at a level higher than 0%, but lower than an equi-velocity point volume percentage, as herein defined, of said carbon-containing gas.

19. A dry etching apparatus comprising:
a process chamber in which a semiconductor workpiece is to be placed;
a first device configured to introduce an etching gas comprising a carbon-free, fluorine-containing gas and a fluorine-free, carbon-containing gas into said process chamber; and
a second device configured to generate a plasma from said etching gas.

20. The apparatus according to claim 19, wherein said semiconductor workpiece comprises a semiconductor and an oxide film provided on the semiconductor, and said apparatus further comprises a third device configured to control a ratio between said fluorine-containing gas and said carbon-containing gas such that one of the semiconductor and the oxide film is etched selectively with respect to the other.
